(19) United States
(12) Patent Application Publication
(10) Pub. No.: US 2002/0139997 A1
(43) Pub. Date: Oct. 3, 2002

(54) Compound semiconductor device having heterojunction bipolar transistor reduced in collector contact resistance by delta-doped region and process for fabrication thereof

(76) Inventors: Masahiro Tanomura, Tokyo (JP); Hidenori Shimawaki, Tokyo (JP)

Correspondence Address: MCGINN & GIBB, PLLC, 8321 OLD COURTHOUSE ROAD, SUITE 200, VIENNA, VA, 22182-3817, US

(21) Appl. No.: 10/107,822

(22) Filed: Mar. 28, 2002

(30) Foreign Application Priority Data
Mar. 29, 2001 (JP) 2001-94793

(51) Int. Cl. H01L 31/0328

(52) U.S. Cl. 257/197

(57) ABSTRACT

A heterojunction bipolar transistor has a multi-layered compound semi-conductor structure consisting of a sub-collector layer, a collector layer, a base layer, an emitter layer and an emitter cap layer, and a heavily doped extremely narrow delta-doped sheet region is formed in a surface portion of the sub-collector layer, wherein an emitter electrode, a base electrode and a collector electrode are formed on the emitter cap layer, base layer and the heavily-doped extremely narrow delta-doped sheet region so that the collector contact resistance is reduced without sacrifice of the current gain and reliability of transistor.

### FIELD OF THE INVENTION

This invention relates to a compound semiconductor device and, more particularly, to a compound semiconductor device having a heterojunction bipolar transistor and a process for fabrication thereof.

### DESCRIPTION OF THE RELATED ART

A typical example of the heterojunction bipolar transistor is fabricated on a semi-insulating gallium arsenide substrate. A sub-collector layer, a collector layer, a base layer, an emitter layer and an emitter cap layer are epitaxially grown on the semi-insulating gallium arsenide substrate, and an emitter electrode, a base electrode and a collector electrode are respectively formed on the emitter cap layer, the base layer and the sub-collector layer. The sub-collector layer, collector layer, base layer, emitter layer and emitter electrode layer are formed of compound semiconductor, and the electrodes are formed of alloy or metal. When the base electrode is appropriately biased, current flows between the collector electrode and the emitter electrode. The amount of current is controlled with the bias voltage at the base electrode. Thus, the heterojunction bipolar transistor behaves as similar to the conventional bipolar transistor.

The heterojunction bipolar transistor is available for amplifiers. I order to enhance the efficiency, which is one of the important factors for a high-performance amplifier, it is necessary to reduce the collector resistance. The collector resistance is broken down into two components. One of the components is the resistance against the current flowing through the sub-collector layer, and is hereinbelow referred to as “access resistance”. The other component is the resistance against the current flowing through the boundary between the collector layer and the collector electrode, and is hereinbelow referred to as “contact resistance”.

The sheet resistance is the major factor for changing the access resistance. When the sub-collector layer is increased in thickness, or when the dopant impurity is increased, the sheet resistance is reduced. The heterojunction bipolar transistors have the sub-collector layers, which are fallen within the range between 100 nanometers thick and 1000 nanometers thick. On the other hand, the dopant concentration in the sub-collector layers ranges from 1×10¹⁸/cm³ to 6×10¹⁸/cm³. When the sub-collector layer exceeds over 1000 nanometers thick, the fabrication process becomes complicated. On the other hand, when the dopant concentration exceeds 6×10¹⁸/cm³, the current gain is lowered, and the heterojunction bipolar transistor is degraded in reliability. Thus, the process and current gain set the limits on the sub-collector layer.

Another approach to the high-performance heterojunction bipolar transistor is to reduce the contact resistance. The higher the dopant concentration, the lower the contact resistance. The sub-collector layer is locally increased in dopant concentration through regrowing the contact regions or ion-implantation. However, the regrowth and ion-implantation require heat treatment at least 500 degrees in centigrade. While the contact region is being treated with heat, the heat reaches the remaining region of the sub-collector region, and gives rise to various problems such as the reduction in current gain and the degradation in reliability. Moreover, the fabrication process is complicated. Thus, the regrowth and ion-implantation are not employable for the reduction of contact resistance.

A solution is disclosed in Japanese Patent Application laid-open No. 3-236224. The solution disclosed in the Japanese Patent Publication laid-open is hereinbelow referred to as “first prior art”. The first prior art is to treat the contact region with ammonium sulfide. The author insists that the contact resistance is reduced through the treatment with ammonium sulfide without undesirable heat treatment. Another solution is disclosed in Japanese Patent Application laid-open No. 2-256243, and is hereinbelow referred to as “second prior art”. The second prior art is to insert an indium-gallium-arsenide layer between the sub-collector layer and the collector layer. The indium-gallium arsenide layer is heavier in dopant concentration than the collector layer and the sub-collector layer, and is designed to absorb the internal stress due to the misfit. An example of the indium-gallium-arsenide layer is 16.7 nanometers thick.

A problem inherent in the first prior art is unstable contact resistance. Although the first prior art does not require the heat treatment for the contact region, the first prior art heterojunction bipolar transistor is to be tested in high temperature atmosphere after the completion of the fabrication process, and the sulfur, which was introduced through the treatment with the ammonium sulfide, is less stable in the collector contact region. The unstable sulfur is causative of fluctuation in contact resistance.

A problem inherent in the second prior art is reduction in current gain due to dislocation in the base layer. The indium gallium arsenide layer is designed to be thick enough to absorb the internal stress due to the misfit. However, it is impossible to perfectly eliminate the internal stress from the boundaries. The dislocation takes place at the boundaries due to the internal stress, and is transferred to the base layer. The dislocation is causative of the reduction in current gain, and the manufacturer suffers from the low reliability of the second prior art heterojunction bipolar transistor.

### SUMMARY OF THE INVENTION

It is therefore an important object of the present invention to provide a compound semiconductor device having a heterojunction bipolar transistor, which is large in current gain, highly reliable and low in contact resistance without fluctuation in the test after completion of the fabrication process.

It is also an important object of the present invention to provide a process, through which the compound semiconductor device is fabricated.

To accomplish the object, the present invention proposes to produce a heavily doped delta-doped region in a sub-collector layer for creating an ohmic contact to a collector electrode.

In accordance with one aspect of the present invention, there is provided a compound semiconductor device having a heterojunction bipolar transistor fabricated on a semi-insulating substrate of a first compound semiconductor, and the heterojunction bipolar transistor comprises a collector layer formed of a second compound semiconductor epitaxially grown on the first compound semiconductor and formed with a delta-doped sheet region larger in dopant concentration than the remaining portion of the collector layer, a base layer formed of a third compound semiconductor epitaxially grown on the second compound semiconductor, an emitter layer formed of a fourth compound semiconductor epitaxially grown on the third compound semiconductor, an emitter electrode electrically connected to the emitter layer, a base electrode electrically connected to the base layer and a collector electrode held in contact with the delta-doped sheet region so as to electrically connected to the collector layer.

In accordance with another aspect of the present invention, there is provided a process for fabricating a compound semiconductor device having at least one heterojunction bipolar transistor, comprising the steps of a) preparing a semi-insulating substrate of a first compound semiconductor, b) epitaxially growing a second compound semiconductor, third compound semiconductor and fourth semiconductor on the first compound semiconductor for forming a multi-layered compound semiconductor structure, a heavily doped region being formed in a surface portion of the second compound semiconductor through a delta-doping technique, and c) completing a heterojunction bipolar transistor by selectively carrying out an etching and a deposition of alloy on the multi-layered compound semiconductor structure.

### BRIEF DESCRIPTION OF THE DRAWINGS

The features and advantages of the compound semiconductor device and the fabrication process thereof will be more clearly understood from the following description taken in conjunction with the accompanying drawings, in which

FIG. 1 is a cross sectional schematic view showing the structure of a heterojunction bipolar transistor according to the present invention,

FIGS. 2 to 4 are cross sectional schematic views showing a process for fabricating the heterojunction bipolar transistor shown in FIG. 1,

FIG. 5 is a cross sectional schematic view showing the structure of another heterojunction bipolar transistor according to the present invention,

FIGS. 6 to 8 are cross sectional schematic views showing a process for fabricating the heterojunction bipolar transistor shown in FIG. 5,

FIG. 9 is a cross sectional schematic view showing the structure of yet another heterojunction bipolar transistor according to the present invention,

FIGS. 10 to 12 are cross sectional schematic views showing a process for fabricating the heterojunction bipolar transistor shown in FIG. 9;

FIG. 13 is a diagram showing the energy band created in the heterojunction bipolar transistor shown in FIG. 5, and

FIG. 14 is a diagram showing the energy band created in the heterojunction bipolar transistor shown in FIG. 9.

### DESCRIPTION OF THE PREFERRED EMBODIMENTS

A compound semiconductor device embodying the present invention includes at least one heterojunction bipolar transistor, and the heterojunction bipolar transistor has a multiple-layered structure of compound semiconductor. The multiple-layered structure includes compound semiconductor layers serving as a sub-collector layer, a collector layer, a base layer and an emitter layer. A collector electrode, a base electrode and an emitter electrode are formed on the sub-collector layer, the base layer and the emitter layer, respectively. A delta-doped sheet region is formed in a surface portion of the sub-collector layer, and serves as a collector contact region. The collector electrode is formed on the sub-collector layer so that the collector electrode and the delta-doped sheet region form an ohmic contact.

The delta-doped sheet region is different from the thermal diffusion and ion-implantation, and a heavily doped extremely thin region is formed in the sub-collector layer through the delta-doping technique. The delta-doping technique is used for an extremely thin layer, which is of the order of several nanometers thick and which has the dopant concentration equal to or greater than 1×10^{18 cm}⁻³. The delta-doped sheet region is produced during the epitaxial growth of the multi-layered structure, and any heat treatment is not required for the activation of the dopant impurity. Any sulfur is not introduced into the delta-doped sheet region. Any indium gallium arsenide layer is not required for the boundary between the sub-collector. Thus, the multi-layered structure is free from the undesirable heat treatment, unstable sulfur and dislocation due to the indium gallium arsenide layer. This results in a large current gain, high reliability and a low contact resistance between the collector electrode and the delta-doped sheet region. The delta-doped sheet region has the sheet concentration equal to or greater than 4×10¹²/cm² and, accordingly, effective volumetric concentration equal to or greater than 8×10¹⁸/cm³. Thus, the collector contact region is heavily doped with the dopant impurity so that the contact resistance is lowered. The delta-doped sheet region is free from the dislocation, and enhances the reliability of the heterojunction bipolar transistor.

The sub-collector layer may be implemented by a first sub-collector layer and a second sub-collector 1 layer. The second sub-collector layer is inserted between the first sub-collector layer and the collector layer, and is different in substance from the first sub-collector layer and the collector layer. Even when certain compound semiconductor is used for both of the collector layer and the first-collector layer, the second sub-collector layer permits the manufacturer to use a first kind of etchant large in selectivity between the collector layer and the second sub-collector layer and, thereafter, a second kind of etchant large in selectivity between the second sub-collector layer and the first sub-collector layer. As a result, the delta-doped in the first sub-collector layer is exactly exposed.

When the first collector layer, the second sub-collector layer and the collector are formed of gallium arsenide (GaAs), indium gallium phosphide (InGaP)/indium gallium arsenic phosphide (InGaAsP) and gallium arsenide (GaAs), respectively, etching solution in the sulfuric acid series exhibits a large selectivity between the gallium arsenide and the indium gallium arsenide/indium gallium arsenic phosphide so that the delta-doped sheet region is exactly exposed.

If the first sub-collector layer, the second sub-collector layer and the collector layer are formed of gallium arsenide, aluminum gallium arsenide and gallium arsenide, etchant in citric acid series and dry etchant in chlorine series exhibits a large selectivity between the gallium arsenide and the aluminum gallium arsenide so that the delta-doped sheet region is exactly exposed.

The sub-collector layer may further include a third sub-collector layer between the second sub-collector layer and the collector layer. In this instance, even if the collector layer is formed of non-doped compound semiconductor or lightly-doped compound semiconductor equal to or less than 1×10¹⁶/cm³, the third sub-collector layer is designed to make the potential barrier to electron low. When the first sub-collector layer is formed of gallium arsenide (GaAs), the second sub-collector layer is formed of indium gallium phosphide (InGaP)/aluminum gallium arsenide (AlGaAs)/indium gallium arsenic phosphide (InGaAsP) and the collector layer is formed of gallium arsenide (GaAs) and indium gallium phosphide (InGaP)/aluminum gallium arsenide (AlGaAs)/indium gallium arsenic phosphide (InGaAsP), the third sub-collector may be formed of gallium arsenide.

First Embodiment

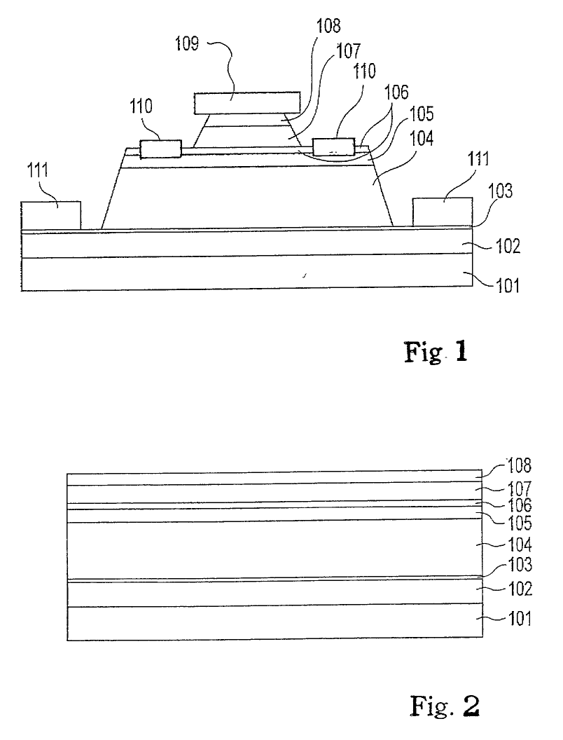

FIG. 1 shows the structure of a heterojunction bipolar transistor embodying the present invention. The heterojunction bipolar transistor is fabricated on a semi-insulating substrate 101 of gallium arsenide, and comprises a multi-layered compound semiconductor structure. The multi-layered compound semiconductor structure includes a sub-collector layer 102 of n-type gallium arsenide (GaAs) and a collector layer 104 of n-type or non-doped gallium arsenide (GaAs).

The sub-collector layer 102 is formed on the major surface of the semi-insulating substrate 101, and have a delta-doped sheet region 103 in a surface portion thereof The delta-doped sheet region 103 is doped with n-type dopant impurity, and has the sheet concentration equal to or greater than 4×10¹²/cm². The delta-doped sheet region 103 is larger in dopant concentration than the remaining portion of the sub-collector layer 102. The collector layer 104 is formed on the sub-collector layer 102, and makes the delta-doped sheet region 103 partially exposed.

The multi-layered compound semiconductor structure further includes a base layer 105 of p-type gallium arsenide (GaAs), an emitter layer 106 of n-type indium gallium phosphide (InGaP) or n-type aluminum gallium arsenide (AlGaAs) an emitter cap layer 107 of n-type gallium arsenide (GaAs) and another emitter cap layer 108 of n-type indium gallium arsenide (InGaAs). The emitter cap layers 107/108 make the peripheral region of the emitter layer 106 exposed. Thus, the sub-collector layer 102, collector layer 104, base layer 105, emitter layer 106 and emitter cap layers 107/108 form the multi-layered compound semiconductor structure on the semi-insulating substrate 101.

The heterojunction bipolar transistor further comprises an emitter electrode 109 of tungsten silicide (WSi), a base electrode 110 of platinum-titanium-platinum-gold alloy (Pt/Ti/Pt/Au) and a collector electrode 111 of nickel-germanium gold-gold (Ni/AuGe/Au) alloy. The emitter electrode 109 is held in contact with the emitter cap layer 108. The base electrode 110 penetrates through the emitter layer 106, and is held in contact with the base layer 105. The collector electrode 111 is held in contact with the delta-doped sheet region 103.

Although the heterojunction bipolar transistor behaves as similar to the prior art heterojunction bipolar transistors, the heterojunction bipolar transistor according to the present invention exhibits transistor characteristics better than those of the prior art heterojunction bipolar transistors.

The heterojunction bipolar transistor is fabricated through a process described hereinbelow in detail. First, the n-type gallium arsenide, n-type or non-doped gallium arsenide, p-type gallium arsenide, n-type indium gallium phosphide or n-type aluminum gallium arsenide, n-type gallium arsenide and the n-type indium gallium arsenide are epitaxially grown on the major surface of the semi-insulating gallium arsenide substrate 101 by using an appropriate epitaxial growing technique. While those kinds of compound semiconductor are being grown, the delta-doped sheet region 103 is produced through a delta-doping technique. Thus, the compound semiconductor layers 102, 104, 105, 106, 107 and 108 are epitaxially grown on the semi-insulating substrate 101, and an epitaxial wafer is obtained as shown in FIG. 2. Any heat treatment is not carried out after the epitaxial growth of the multi-layered compound semiconductor structure.

Subsequently, tungsten silicide (WSi) is deposited over the entire surface of the uppermost indium gallium arsenide layer 108 by using a sputtering. A photo-resist mask (not shown) is patterned on the tungsten silicide layer by using a photo-lithography, and the tungsten suicide layer is partially removed from the multi-layered compound semiconductor structure by using a dry etching. The photo-resist mask is stripped off. Thus, the emitter electrode 109 is formed from the tungsten silicide layer.

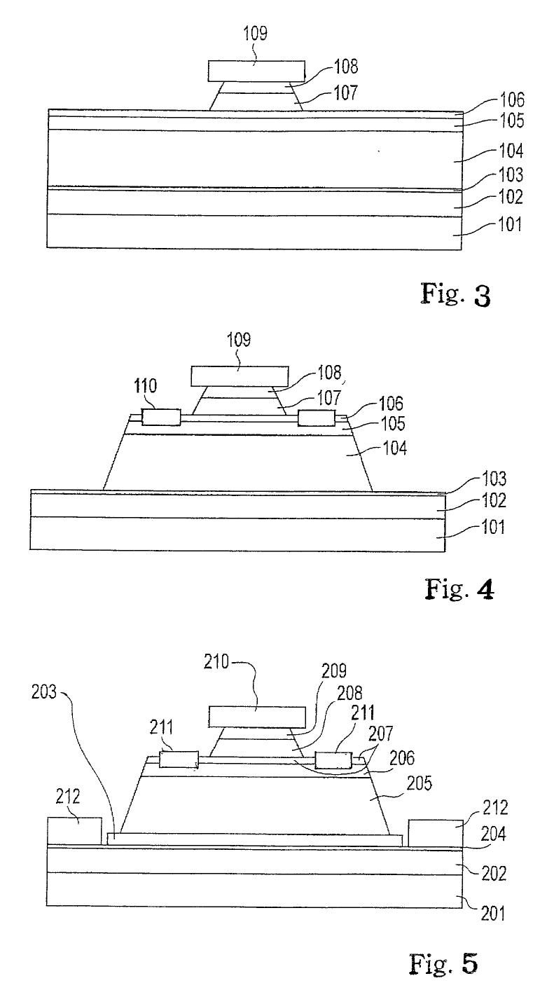

Subsequently, using the emitter electrode 109 as an etching mask, the n-type indium gallium arsenide layer 108 and the n-type gallium arsenide layer 107 are selectively removed from the multi-layered compound semiconductor structure by using etching solution in the sulfuric acid series. The wet etching is continued until the n-type indium gallium phosphide layer or n-type aluminum gallium arsenide layer 106 is exposed to the space around the emitter cap layers 107/108. The resultant structure is shown in FIG. 3.

Subsequently, a photo-resist mask (not shown) is formed on the entire surface of the resultant structure, and has a hollow space over the peripheral area of the n-type indium gallium phosphide layer or n-type aluminum gallium arsenide layer 106. Platinum, titanium, platinum and gold are successively deposited over the entire surface by using an evaporation technique. The photo-resist mask is lift off. Then, the platinum layer, titanium layer, platinum layer and gold layer are left on the peripheral area of the n-type indium gallium phosphide layer or n-type aluminum gallium arsenide layer 106. The platinum layer, titanium layer, platinum layer and the gold layer are heated in certain atmosphere containing inert gas and hydrogen at 400 degrees to 500 degrees in centigrade for ten to tens minutes. The platinum layer, titanium layer, platinum layer and gold layer are sintered and alloyed in the high temperature atmosphere. The platinum-titanium- platinum- gold alloy penetrates through the n-type indium gallium phosphide layer or n-type aluminum gallium arsenide layer 106, and reaches the p-type gallium arsenide layer 105. Thus, the base electrode 110 is formed of the platinum-titanium-platinum-gold alloy as shown in FIG. 4.

A photo-resist mask is patterned on the resultant structure by using the photo-lithography. Using the photo-resist mask, the n-type indium gallium phosphide layer/n-type aluminum gallium arsenide layer 106, p-type gallium arsenide layer 105 and the n-type or non-doped gallium arsenide layer 104 are selectively etched away so as to form the n-type emitter layer 106, p-type base layer 105 and the n-type/non-doped collector layer 104. Upon completion of the etching, the photo-resist mask is stripped off. Then, the delta-doped sheet region 103 is exposed to the space around the n-type/non-doped collector layer 104 as shown in FIG. 4.

A photo-resist mask is patterned on the resultant structure by using the photo-lithography. The photo-resist mask has a hollow space over a certain area of the delta-doped sheet region 103 assigned to the collector electrode 111. Nickel, gold-germanium and gold are evaporated on the entire surface of the resultant structure, and the photo-resist mask is lifted off. Then, the nickel, gold-germanium and the gold are left on the area assigned to the collector electrode 111. The metals are alloyed so that the collector electrode 111 is formed on the delta-doped sheet region 103 as shown in FIG. 1.

As will be understood from the foregoing description, the collector electrode 111 is electrically connected to the sub-collector layer 102 through the heavily doped extremely thin delta-doped sheet region 103. Any high temperature heat treatment is not required after the epitaxial growth of the multi-layered compound semiconductor structure, and the delta-doped sheet region 103 never contains unstable sulfur. The delta-doped sheet region 103 is same in substance as the sub-collector layer 103 and the collector layer 104, and is free from the serious dislocation due to the lattice-mismatch. For this reason, the heterojunction bipolar transistor achieves a large current gain, and is highly reliable.

In this instance, the sub-collector layer 102 and the collector layer 104 as a whole constitute a collector layer, and the emitter layer 106 and the emitter cap layers 107/108 form in combination an emitter layer.

Second Embodiment

FIG. 5 shows the structure of a heterojunction bipolar transistor incorporated in another compound semiconductor device embodying the present invention. The heterojunction bipolar transistor is fabricated on a semi-insulating substrate 201 of gallium arsenide, and has a multi-layered compound semiconductor structure. The multi-layered compound semiconductor structure includes a first sub-collector layer 202 of n-type gallium arsenide (GaAs), a second sub-collector layer 203 of n-type indium gallium phosphide (InGaP) and a collector layer 205 of n-type or non-doped gallium arsenide (GaAs).

The first sub-collector layer 202 is formed on the major surface of the semi-insulating substrate 201, and have a delta-doped sheet region 204 in a surface portion thereof The delta-doped sheet region 204 is doped with n-type dopant impurity, and has the sheet concentration equal to or greater than 4×10¹²/cm². The delta-doped sheet region 204 is larger in dopant concentration than the remaining portion of the first sub-collector layer 202. The second sub-collector layer 204 is formed on the central area of the delta-doped sheet region 204, and, accordingly, permits the peripheral area to be exposed. The collector layer 205 is formed on the second sub-collector layer 203.

The multi-layered compound semiconductor structure further includes a base layer 206 of p-type gallium arsenide (GaAs), an emitter layer 207 of n-type indium gallium phosphide (InGaP) or n-type aluminum gallium arsenide (AlGaAs), an emitter cap layer 208 of n-type gallium arsenide (GaAs) and another emitter cap layer 209 of n-type indium gallium arsenide (InGaAs). The emitter cap layers 208/209 make the peripheral region of the emitter layer 207 exposed. Thus, the delta-doped sheet region 204 in the first sub-collector layer 202, the emitter layer 207 and the emitter cap layer 209 are exposed.

The heterojunction bipolar transistor further comprises an emitter electrode 210 of tungsten silicide (WSi), a base electrode 211 of platinum-titanium-platinum-gold alloy (Pt/Ti/Pt/Au) and a collector electrode 212 of nickel-germanium/gold-gold (Ni/AuGe/Au) alloy. The emitter electrode 210 is held in contact with the emitter cap layer 209. The base electrode 211 penetrates through the emitter layer 207, and is held in contact with the base layer 206. The collector electrode 212 is held in contact with the delta-doped sheet region 204.

Although the heterojunction bipolar transistor behaves as similar to the prior art heterojunction bipolar transistors, the heterojunction bipolar transistor according to the present invention exhibits transistor characteristics better than those of the prior art heterojunction bipolar transistors.

The heterojunction bipolar transistor is fabricated through a process described hereinbelow in detail. First, the n-type gallium arsenide, n-type indium gallium phosphide, n-type or non-doped gallium arsenide, p-type gallium arsenide, n-type indium gallium phosphide or n-type aluminum gallium arsenide, n-type gallium arsenide and the n-type indium gallium arsenide are epitaxially grown on the major surface of the semi-insulating gallium arsenide substrate 101 by using the epitaxial growth technique same as that of the process for fabricating the heterojunction bipolar transistor implementing the first embodiment. While those kinds of compound semiconductor are being grown, the delta-doped sheet region 204 is produced through the delta-doping technique. Thus, the compound semiconductor layers 202, 204, 203, 205, 206, 207, 208 and 209 are epitaxially grown on the semi-insulating substrate 201, and an epitaxial wafer is obtained as shown in FIG. 6. Any heat treatment is not carried out after the epitaxial growth of the multi-layered compound semiconductor structure.

Subsequently, tungsten suicide (WSi) is deposited over the entire surface of the uppermost indium gallium arsenide layer 209 by using a sputtering. A photo-resist mask (not shown) is patterned on the tungsten silicide layer by using the photo-lithography, and the tungsten suicide layer is partially removed from the multi-layered compound semiconductor structure by using a dry etching. The photo-resist mask is stripped off. Thus, the emitter electrode 210 is formed from the tungsten silicide layer.

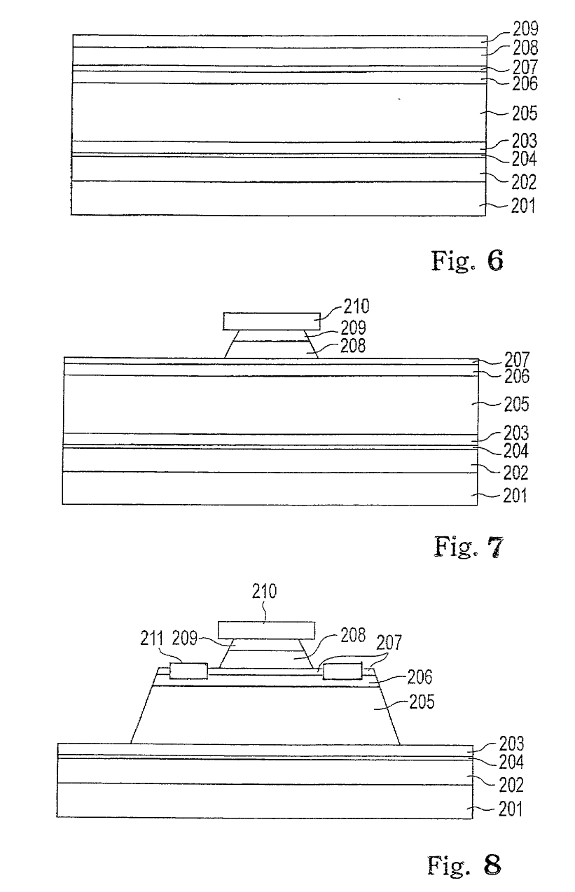

Subsequently, using the emitter electrode 210 as an etching mask, the n-type indium gallium arsenide layer 209 and the n-type gallium arsenide layer 208 are selectively removed from the multi-layered compound semiconductor structure by using etching solution in the sulfuric acid series. The wet etching is continued until the n-type indium gallium phosphide layer or n-type aluminum gallium arsenide layer 207 is exposed to the space around the emitter cap layers 208/209. The resultant structure is shown in FIG. 7.

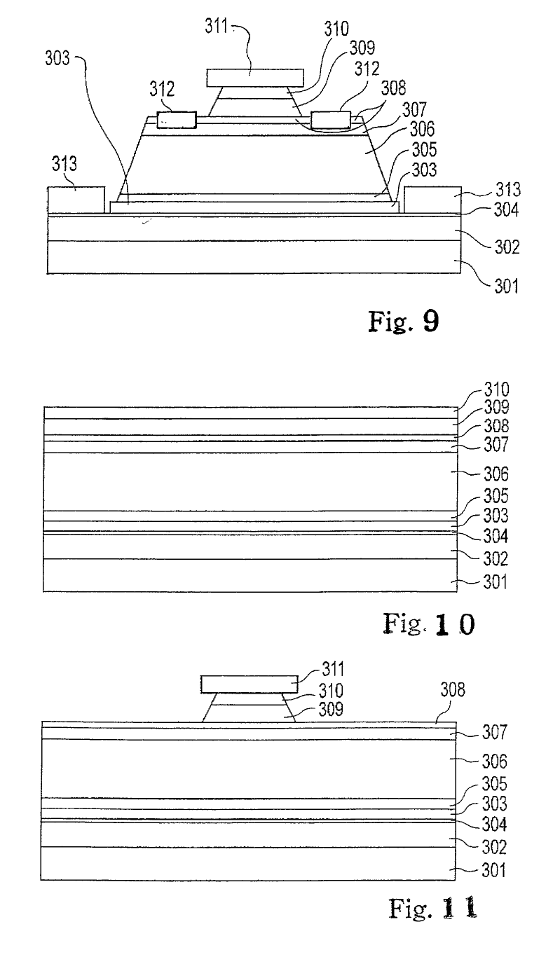

Subsequently, a photo-resist mask (not shown) is formed on the entire surface of the resultant structure, and has a hollow space over the peripheral area of the n-type indium gallium phosphide layer or n-type aluminum gallium arsenide layer 207. Platinum, titanium, platinum and gold are successively deposited over the entire surface by using the evaporation technique. The photo-resist mask is lift off. Then, the platinum layer, titanium layer, platinum layer and gold layer are left on the peripheral area of the n-type indium gallium phosphide layer or n-type aluminum gallium arsenide layer 207. The platinum layer, titanium layer, platinum layer and the gold layer are heated so as to be sintered and alloyed in the high temperature atmosphere. The platinum-titanium-platinum-gold alloy penetrates through the n-type indium gallium phosphide layer or n-type aluminum gallium arsenide layer 207, and reaches the p-type gallium arsenide layer 206. Thus, the base electrode 211 is formed of the platinum-titanium-platinum-gold alloy as shown in FIG. 8.

A photo-resist mask is patterned on the resultant structure by using the photo-lithography. Using the photo-resist mask, the n-type indium gallium phosphide layer/n-type aluminum gallium arsenide layer 207 is removed by using etching solution in the hydrochloric acid series. Subsequently, the p-type gallium arsenide layer 206 and the n-type or non-doped gallium arsenide layer 205 are selectively etched away by using the etching solution in the sulfuric acid series so as to expose the second sub-collector layer 203. The n-type indium gallium phosphide layer/n-type aluminum gallium arsenide layer 207, p-type gallium arsenide layer 206 and the n-type or non-doped gallium arsenide layer 205 are formed into the n-type emitter layer 207, p-type base layer 206 and the n-type/non-doped collector layer 205, respectively. The etching solution in the sulfuric acid has a large selectivity between the gallium arsenide and the indium gallium phosphide so that the second sub-collector layer 203 is exactly exposed without being seriously etched as shown in FIG. 8.

Subsequently, the second sub-collector layer 203 is etched by using etching solution in the hydrochloric acid series so as to expose the delta-doped sheet region 204. The etching solution in the hydrochloric acid series has a large selectivity between the indium gallium phosphide and the gallium arsenide so that the delta-doped sheet region 204 is exposed without being seriously etched.

Upon completion of the etching, the photo-resist mask is stripped off. Then, the delta-doped sheet region 204 is exposed to the space around the n-type/non-doped collector layer 205.

A photo-resist mask is patterned on the resultant structure by using the photo-lithography. The photo-resist mask has a hollow space over a certain area of the delta-doped sheet region 204 assigned to the collector electrode 212. Nickel, gold-germanium and gold are evaporated on the entire surface of the resultant structure, and the photo-resist mask is lifted off. Then, the nickel, gold-germanium and the gold are left on the area assigned to the collector electrode 111. The metals are alloyed so that the collector electrode 212 is formed on the delta-doped sheet region 204 as shown in FIG. 5.

As will be understood from the foregoing description, the collector electrode 212 is electrically connected to the first sub-collector layer 202 through the heavily doped extremely thin delta-doped sheet region 204. Any high temperature heat treatment is not required after the epitaxial growth of the multi-layered compound semiconductor structure, and the delta-doped sheet region 204 never contains unstable sulfur. For this reason, the heterojunction bipolar transistor achieves a large current gain, and is highly reliable. The second sub-collector layer 203 permits the etching solution to expose the heavily doped extremely narrow delta-doped sheet region 204 without serious damage to the delta-doped sheet region 204. Thus, the second sub-collector layer 203 enhances the controllability of the etching.

Third Embodiment

FIG. 9 shows the structure of a heterojunction bipolar transistor incorporated in yet another compound semiconductor device embodying the present invention. The heterojunction bipolar transistor is fabricated on a semi-insulating substrate 301 of gallium arsenide, and has a multi-layered compound semiconductor structure. The multi-layered compound semiconductor structure includes a first sub-collector layer 302 of n-type gallium arsenide (GaAs), a second sub-collector layer 303 of n-type indium gallium phosphide (InGaP), a third sub-collector layer 305 of n-type gallium arsenide (GaAs) and a collector layer 306 of n-type or non-doped gallium arsenide (GaAs).

The first sub-collector layer 302 is formed on the major surface of the semi-insulating substrate 301, and is doped at 1×10¹⁸-6×10¹⁸/cm³ or less. The first sub-collector layer 302 has a delta-doped sheet region 304 in a surface portion thereof. The delta-doped sheet region 304 is doped with n-type dopant impurity, and has the sheet concentration equal to or greater than 4×10¹²/cm². The second sub-collector layer 303 is formed on the central area of the delta-doped sheet region 304, and, accordingly, permits the peripheral area to be exposed. The second sub-collector layer 303 is also doped at 1×10¹⁸-6×10¹⁸/cm³ or less. The second sub-collector layer 303 is overlaid by the third sub-collector layer 305, and the third sub-collector layer 305 is also doped at 1×10¹⁸-6×10¹⁸/cm³ or less. The collector layer 205 is formed on the third sub-collector layer 305. In case where the collector layer 205 is formed of the n-type gallium arsenide, the dopant concentration is equal to or less than 1×10¹⁶/cm³.

The multi-layered compound semiconductor structure further includes a base layer 307 of p-type gallium arsenide (GaAs), an emitter layer 308 of n-type indium gallium phosphide (InGaP) or n-type aluminum gallium arsenide (AlGaAs), an emitter cap layer 309 of n-type gallium arsenide (GaAs) and another emitter cap layer 310 of n-type indium gallium arsenide (InGaAs). The emitter cap layers 309/310 make the peripheral region of the emitter layer 308 exposed. Thus, the delta-doped sheet region 304 in the first sub-collector layer 302, the emitter layer 308 and the emitter cap layer 310 are exposed. The heterojunction bipolar transistor further comprises an emitter electrode 311 of tungsten silicide (WSi), a base electrode 312 of platinum-titanium-platinum-gold alloy (Pt/Ti/Pt/Au) and a collector electrode 313 of nickel-germanium/gold-gold (Ni/AuGe/Au) alloy. The emitter electrode 311 is held in contact with the emitter cap layer 310. The base electrode 312 penetrates through the emitter layer 308, and is held in contact with the base layer 307. The collector electrode 313 is held in contact with the delta-doped sheet region 304.

Although the heterojunction bipolar transistor behaves as similar to the prior art heterojunction bipolar transistors, the heterojunction bipolar transistor according to the present invention exhibits transistor characteristics better than those of the prior art heterojunction bipolar transistors.

The heterojunction bipolar transistor is fabricated through a process described hereinbelow in detail. First, the n-type gallium arsenide, n-type indium gallium phosphide, n-type gallium arsenide, n-type or non-doped gallium arsenide, p-type gallium arsenide, n-type indium gallium phosphide or n-type aluminum gallium arsenide, n-type gallium arsenide and the n-type indium gallium arsenide are epitaxially grown on the major surface of the semi-insulating gallium arsenide substrate 301 by using the epitaxial growth technique same as that of the process for fabricating the heterojunction bipolar transistor implementing the first embodiment. While those kinds of compound semiconductor are being grown, the delta-doped sheet region 304 is produced through the delta-doping technique. Thus, the compound semiconductor layers 302, 303, 305, 306, 307, 308, 309 and 310 are epitaxially grown on the semi-insulating substrate 301, and an epitaxial wafer is obtained as shown in FIG. 10. Any heat treatment is not carried out after the epitaxial growth of the multi-layered compound semiconductor structure.

Subsequently, tungsten silicide (WSi) is deposited over the entire surface of the uppermost indium gallium arsenide layer 310 by using a sputtering. A photo-resist mask (not shown) is patterned on the tungsten silicide layer by using the photo-lithography, and the tungsten silicide layer is partially removed from the multi-layered compound semiconductor structure by using a dry etching. The photo-resist mask is stripped off. Thus, the emitter electrode 311 is formed from the tungsten silicide layer.

Subsequently, using the emitter electrode 311 as an etching mask, the n-type indium gallium arsenide layer 310 and the n-type gallium arsenide layer 309 are selectively removed from the multi-layered compound semiconductor structure by using the etching solution in the sulfuric acid series. The wet etching is continued until the n-type indium gallium phosphide layer or n-type aluminum gallium arsenide layer 308 is exposed to the space around the emitter cap layers 310/309. The resultant structure is shown in FIG. 11.

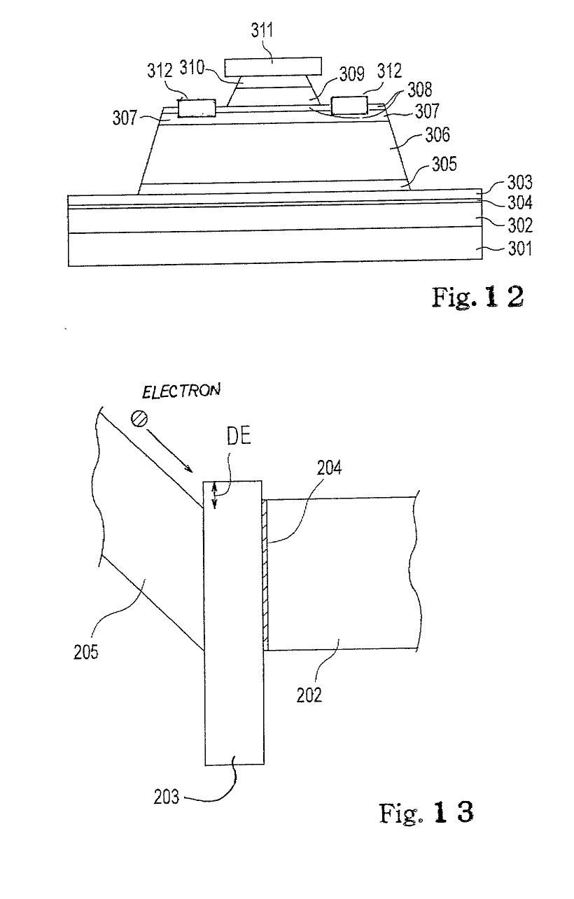

Subsequently, a photo-resist mask (not shown) is formed on the entire surface of the resultant structure, and has a hollow space over the peripheral area of the n-type indium gallium phosphide layer or n-type aluminum gallium arsenide layer 308. Platinum, titanium, platinum and gold are successively deposited over the entire surface by using the evaporation technique. The photo-resist mask is lift off. Then, the platinum layer, titanium layer, platinum layer and gold layer are left on the peripheral area of the n-type indium gallium phosphide layer or n-type aluminum gallium arsenide layer 308. The platinum layer, titanium layer, platinum layer and the gold layer are heated so as to be sintered and alloyed in the high temperature atmosphere. The platinum-titanium-platinum-gold alloy penetrates through the n-type indium gallium phosphide layer or n-type aluminum gallium arsenide layer 308, and reaches the p-type gallium arsenide layer 307. Thus, the base electrode 312 is formed of the platinum-titanium-platinum-gold alloy as shown in FIG. 12.

A photo-resist mask is patterned on the resultant structure by using the photo-lithography. Using the photo-resist mask, the n-type indium gallium phosphide layer/n-type aluminum gallium arsenide layer 308 is removed by using etching solution in the hydrochloric acid series. Subsequently, the p-type gallium arsenide layer 307, the n-type or non-doped gallium arsenide layer 306 and the n-type gallium arsenide layer 305 are selectively etched away by using the etching solution in the sulfuric acid series so as to expose the second sub-collector layer 303. The n-type indium gallium phosphide layer/n-type aluminum gallium arsenide layer 308, p-type gallium arsenide layer 307, the n-type or non-doped gallium arsenide layer 306 and the n-type gallium arsenide layer 305 are formed into the n-type emitter layer 308, p-type base layer 307, the n-type/non-doped collector layer 306 and the n-type third sub-collector layer 305, respectively. The etching solution in the sulfuric acid has a large selectivity between the gallium arsenide and the indium gallium phosphide so that the second sub-collector layer 303 is exactly exposed without being seriously etched as shown in FIG. 12.

Subsequently, the second sub-collector layer 303 is etched by using etching solution in the hydrochloric acid series so as to expose the delta-doped sheet region 304. The etching solution in the hydrochloric acid series has a large selectivity between the indium gallium phosphide and the gallium arsenide so that the delta-doped sheet region 304 is exposed without being seriously etched.

Upon completion of the etching, the photo-resist mask is stripped off. Then, the delta-doped sheet region 304 is exposed to the space around the n-type third sub-collector layer 305.

A photo-resist mask is patterned on the resultant structure by using the photo-lithography. The photo-resist mask has a hollow space over a certain area of the delta-doped sheet region 304 assigned to the collector electrode 313. Nickel, gold-germanium and gold are evaporated on the entire surface of the resultant structure, and the photo-resist mask is lifted off. Then, the nickel, gold-germanium and the gold are left on the area assigned to the collector electrode 313. The metals are alloyed so that the collector electrode 131 is formed on the delta-doped sheet region 304 as shown in FIG. 9.

As will be understood from the foregoing description, the collector electrode 313 is electrically connected to the first sub-collector layer 302 through the heavily doped extremely thin delta-doped sheet region 304. Any high temperature heat treatment is not required after the epitaxial growth of the multi-layered compound semiconductor structure, and the delta-doped sheet region 304 never contains unstable sulfur. For this reason, the heterojunction bipolar transistor achieves a large current gain, and is highly reliable. The second sub-collector layer 303 permits the etching solution to expose the heavily doped extremely narrow delta-doped sheet region 304 without serious damage. Thus, the second sub-collector layer 303 enhances the controllability of the etching.

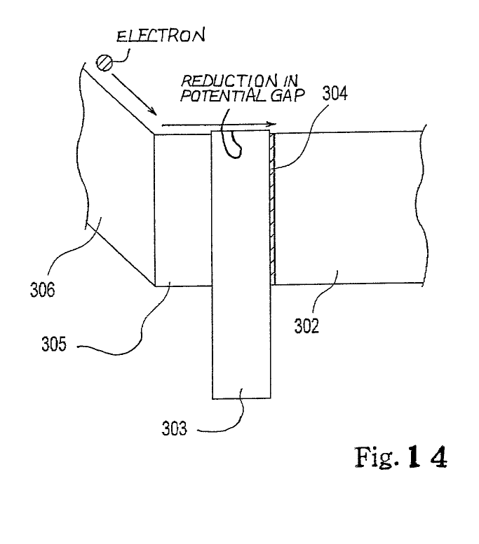

Moreover, the third sub-collector layer 305 reduces the potential gap between the n-type/non-doped collector layer 306 and the n-type second sub-collector layer 305. As described in conjunction with the second embodiment, the n-type/non-doped collector layer 205 is directly held in contact with the second sub-collector layer 203. The collector layer 205 is formed of gallium arsenide, and the second sub-collector 203 is formed of indium gallium phosphide. A large potential gap DE takes place between the n-type/non-doped gallium arsenide collector layer 205 and the n-type indium gallium phosphide sub-collector layer 203 as shown in FIG. 13. The large potential gap DE is the obstacle against the electrons transported into the collector.

On the other hand, the heterojunction bipolar transistor implementing the third embodiment has the third sub-collector layer 305 of n-type gallium arsenide between the n-type/non-doped collector layer 306 and the n-type second sub-collector layer 303. The third sub-collector layer 305 is formed of n-type gallium arsenide, and makes the junction to the second sub-collector layer 303 gentle as shown in FIG. 14. As a result, the electrons are smoothly transported into the collector.

The sheet resistance is reduced in proportional to (1/2)th power of the uppermost sheet concentration of a semiconductor layer held in contact with a metal layer. From this viewpoint, it is preferable to make the sheet resistance of the delta-doped sheet layer 103/204/304 as high as possible. If a sub-collector layer is of the order of 50 nanometers thick and doped at 6×10¹⁸/cm³, or if the sub-collector layer is formed of a misfit system, the dislocation tends to take place in the collector layer, base layer and/or emitter layer laminated thereon. This results in reduction of current gain or poor reliability. The heterojunction bipolar transistors implementing the present invention have the delta-doped sheet regions formed in the sub-collector layers 102/202/302 and doped at 4×10¹²/cm² or more. The effective dopant concentration in the surface regions is so high that the contact resistance is lowered. Thus, the delta-doped sheet regions enhances the current gain and reliability without any dislocation.

Although particular embodiments of the present invention have been shown and described, it will be apparent to those skilled in the art that various changes and modifications may be made without departing from the spirit and scope of the present invention.

The heterojunction bipolar transistor may be a discrete compound semiconductor device or form a part of an integrated circuit device.

What is claimed is:

1. A compound semiconductor device having a heterojunction bipolar transistor fabricated on a semi-insulating substrate of a first compound semiconductor, said heterojunction bipolar transistor comprising:
a collector layer formed of a second compound semiconductor epitaxially grown on said first compound semiconductor, and formed with a delta-doped sheet region larger in dopant concentration than the remaining portion of said collector layer;
a base layer formed of a third compound semiconductor epitaxially grown on said second compound semiconductor;
an emitter layer formed of a fourth compound semiconductor epitaxially grown on said third compound semiconductor;
an emitter electrode electrically connected to said emitter layer;
a base electrode electrically connected to said base layer; and
a collector electrode held in contact with said delta-doped sheet region so as to electrically connected to said collector layer.

2. The compound semiconductor device as set forth in claim 1, in which said delta-doped sheet region has a sheet dopant concentration equal to or greater than 4×10¹²/cm².

3. The compound semiconductor device as set forth in claim 1, in which said collector layer has a sub-collector layer formed on said semi-insulating substrate and an intrinsic collector layer formed on said sub-collector layer, and said delta-doped sheet region is formed in a surface portion of said sub-collector layer.

4. The compound semiconductor device as set forth in claim 3, in which said delta-doped sheet region has a sheet dopant concentration equal to or greater than 4×10¹²/cm², and forms an ohmic contact with an alloy forming said collector electrode.

5. The compound semiconductor device as set forth in claim 3, in which said sub-collector layer and said intrinsic collector layer are formed of said second compound semiconductor in a gallium-arsenide system.

6. The compound semiconductor device as set forth in claim 5, in which said sub-collector layer and said intrinsic collector layer are formed of n-type gallium arsenide and a compound semiconductor selected from the group consisting of n-type gallium arsenide and non-doped gallium arsenide.

7. The compound semiconductor device as set forth in claim 1, in which said collector layer has a first sub-collector layer formed on said semi-insulating substrate, a second sub-collector layer formed on said first sub-collector layer and an intrinsic collector layer formed in said second sub-collector layer, and said delta-doped sheet region is formed in said first sub-collector layer.

8. The compound semiconductor device as set forth in claim 7, in which said delta-doped sheet region has a sheet dopant concentration equal to or greater than 4×10¹²/cm², and forms an ohmic contact with an alloy forming said collector electrode.

9. The compound semiconductor device as set forth in claim 7, in which said first sub-collector layer, said second sub-collector layer and said intrinsic collector layer are formed of said second compound semiconductor in a gallium arsenide-indium gallium phosphide system.

10. The compound semiconductor device as set forth in claim 9, in which said first sub-collector layer and said second sub-collector layer are formed of n-type gallium arsenide and n-type indium gallium phosphide, respectively, and said intrinsic collector layer is formed of a compound semiconductor selected from the group consisting of n-type gallium arsenide and non-doped gallium arsenide.

11. The compound semiconductor device as set forth in claim 1, in which said collector layer has a first sub-collector layer formed on said semi-insulating substrate, a second sub-collector layer formed on said first sub-collector layer, an intrinsic collector layer formed over said second sub-collector layer and a third sub-collector layer formed between said second sub-collector layer and said intrinsic collector layer so as to make the bottom edge of a conduction band gentle, and said delta-doped sheet region is formed in said first sub-collector layer.

12. The compound semiconductor device as set forth in claim 11, in which said delta-doped sheet region has a sheet dopant concentration equal to or greater than 4×10¹²/cm², and forms an ohmic contact with an alloy forming said collector electrode.

13. The compound semiconductor device as set forth in claim 11, in which said first sub-collector layer, said second sub-collector layer, said third sub-collector layer and said intrinsic collector layer are formed of said second compound semiconductor in a gallium arsenide-indium gallium phosphide system.

14. The compound semiconductor device as set forth in claim 13, in which said first sub-collector layer, said second sub-collector layer and said third sub-collector layer are formed of n-type gallium arsenide, n-type indium gallium phosphide and n-type indium gallium phosphide, respectively, and said intrinsic collector layer is formed of a compound semiconductor selected from the group consisting of n-type gallium arsenide and non-doped gallium arsenide.

15. A process for fabricating a compound semiconductor device having at least one heterojunction bipolar transistor, comprising the steps of:
a) preparing a semi-insulating substrate of a first compound semiconductor;
b) epitaxially growing a second compound semiconductor, third compound semiconductor and fourth semiconductor on said first compound semiconductor for forming a multi-layered compound semiconductor structure, a heavily doped region being formed in a surface portion of said second compound semiconductor through a delta-doping technique; and
c) completing a heterojunction bipolar transistor by selectively carrying out an etching and a deposition of alloy on said multi-layered compound semiconductor structure.

16. The process as set forth in claim 15, in which a collector layer, a base layer and an emitter layer are formed from said second compound semiconductor, said third compound semiconductor and said fourth semiconductor in said step c).

17. The process as set forth in claim 15, in which said step c) includes the sub-steps of
c-1) forming an emitter electrode and a base electrode on said fourth compound semiconductor,
c-2) patterning said fourth compound semiconductor and said third compound semiconductor layer into said emitter layer and said base layer, respectively.
c-3) exposing said heavily doped region by partially etching said second compound semiconductor so as to form said collector layer from said second compound semiconductor, and
c-4) forming a collector electrode on said heavily doped region.

18. The process as set forth in claim 17, in which said second compound semiconductor has an etching stopper of a fifth compound semiconductor between a lower portion and an upper portion, and said sub-step c-3) has the sub-steps of
c-3-1) removing said upper portion by using a first etchant having a selectivity between said second compound semiconductor and said fifth compound semiconductor, and
c-3-2) removing said etching stopper by using a second etchant having a selectivity between said fifth compound semiconductor and said second compound semiconductor.

19. The process as set forth in claim 15, in which said heavily doped region has a sheet dopant concentration equal to or greater than 4×10¹²/cm².
